(19) United States
(12) Patent Application Publication
(10) Pub. No.: US 2003/0131797 A1
(43) Pub. Date: Jul. 17, 2003

(54) System for coating items using self-contained vacuum fixture

(76) Inventors: Shawn P. Oglesbee, Ham Lake, MN (US); Duane C. Smallwood, Big Lake, MN (US); Wesley L. Oglesbee, Minneapolis, MN (US)

Correspondence Address: Timothy E. Bianchi, 1225 Polk Place, Columbia Heights, MN, 55421, US

(21) Appl. No.: 10/309,431

(22) Filed: Dec. 3, 2002

Related U.S. Application Data
(60) Provisional application No. 60/337,223, filed on Dec. 3, 2001.
(60) Provisional application No. 60/337,251, filed on Dec. 3, 2001.

(51) Int. Cl. C23C 16/00

(52) U.S. Cl. 118/728

(57) ABSTRACT

A system for coating items using a self-contained vacuum fixture. The system providing lower cost, complexity, and form factor in a coating machine. A self-contained, self-generating vacuum feature avoids the need for an external vacuum supply. The system providing fewer errors and downtime.

### RELATED APPLICATIONS

This patent application claims the benefit under 35 U.S.C. 119 of U.S. Provisional Patent Applications Nos. 60/337,223, filed Dec. 3, 2001, and 60/337,251, filed Dec. 3, 2001.

### FIELD OF THE INVENTION

The present invention relates generally to systems for coating items, and more particularly to a system for spin coating items using a self-contained vacuum fixture.

### BACKGROUND

Coating vacuum systems include a holding device for holding the item to be coated. For example, machines that coat opthalmic lenses use an external vacuum supply which provides vacuum to some of the actuators in the system and provides a vacuum to the holding device. Such machines spin the lens while a chemical process is used to coat the lens.

FIG. 1 is a diagram showing a prior art spin coating system 8 using a holding device 4 requiring an external vacuum source 6 to hold part 5. The prior art spin coating system 8 communicates the vacuum using vacuum input line 7 connected to the external vacuum source 6. The vacuum reaches holding device 4 via vacuum supply line 2 and rotary union 3.

System 8 has several problems. For example, the spinning aspect creates complications in providing vacuum to the holding device 4. In such systems the holding device 4 must receive vacuum during the spinning, or the part 5 to be coated (i.e., lens) will fall.

Another problem is that the external vacuum source 6 and connected vacuum components are prone to failure. Such failures increase downtime and the cost of maintenance.

Another problem is that one type of existing vacuum generating source utilizes an external air supply plumbed to an air driven vacuum generator. This vacuum generation can be problematic due to contaminations and/or insufficient air supply. Air driven vacuum generators also require and use large volumes of air.

Another example of vacuum generation is a central stand-alone electric vacuum pump. This component, too, is prone to failure.

Yet another problem is that external vacuum sources add to the cost of a coating system and the amount of space required to operate the machine.

Thus, there is a need in the art for an improved system for coating items providing reduced downtime, maintenance and cost.

### SUMMARY

The present invention relates to a system for coating items using a self-contained vacuum fixture. The present system solves the problems in the art stated above and other problems not expressly stated herein.

In one embodiment, the system uses a vacuum fixture having a self-contained vacuum feature so that an external vacuum system is not required. The system also does not require the vacuum line and components needed to supply vacuum to the fixture.

In one application, the present system is employed in spin coating machines. It is understood that other applications are possible, and one of skill in the art will appreciate other uses upon reading and understanding the present specification.

This summary is intended to provide an overview of the subject matter of the present patent application. It is not intended to provide an exhaustive or exclusive explanation of the invention. The detailed description is included to provide further information. And the claims appended to the application and their equivalents provide the scope of the invention.

### BRIEF DESCRIPTION OF THE FIGURES

FIG. 1 is a diagram showing a prior art system using a holding device requiring an external vacuum system.

FIG. 2 is a diagram showing a coating system including one embodiment of the self-contained vacuum fixture with self-generated vacuum according to one embodiment of the present system.

FIG. 3 is a top view diagram of a multiple station system showing wash, coat, and cure positions according to one embodiment of the present system.

FIG. 4 is a side view of the system of FIG. 3 according to one embodiment of the present system.

FIG. 5 is a diagram of one example of a self-contained vacuum fixture according to one embodiment of the present system.

FIG. 6 is a diagram of the self-contained vacuum fixture of FIG. 5 in a vacuum released state according to one embodiment of the present system.

FIG. 7 is a diagram of the self-contained vacuum fixture of FIG. 5 in a vacuum held state according to one embodiment of the present system.

FIG. 8 is a side view showing one example of attachment of the vacuum fixture according to one embodiment of the present system.

FIG. 9 is a side view showing one example of attachment of the vacuum fixture according to one embodiment of the present system.

FIG. 10 shows one example of a pick and place application employing the vacuum fixture according to one embodiment of the present system.

FIG. 11 shows one example of a pick and place application employing the vacuum fixture according to one embodiment of the present system.

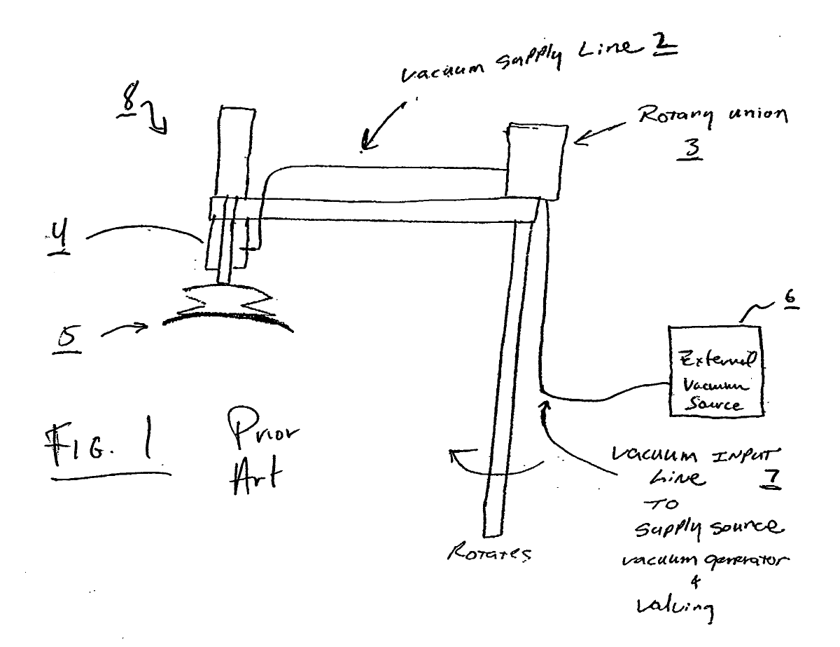

### DETAILED DESCRIPTION

This detailed description is intended to provide details on how to make and use the present invention, including a best mode of the invention. The embodiments provided herein may differ in electrical, mechanical, and chemical nature without departing from the scope of the present invention. It is understood that some organizational variation in the embodiments of apparatus and method provided herein may fall within the scope of the present invention, which is provided by the appended claims and equivalents thereto.

The present system and teachings provide advantages over the previous methods and apparatus, including, but not limited to, solving the problems stated in the art in the Background.

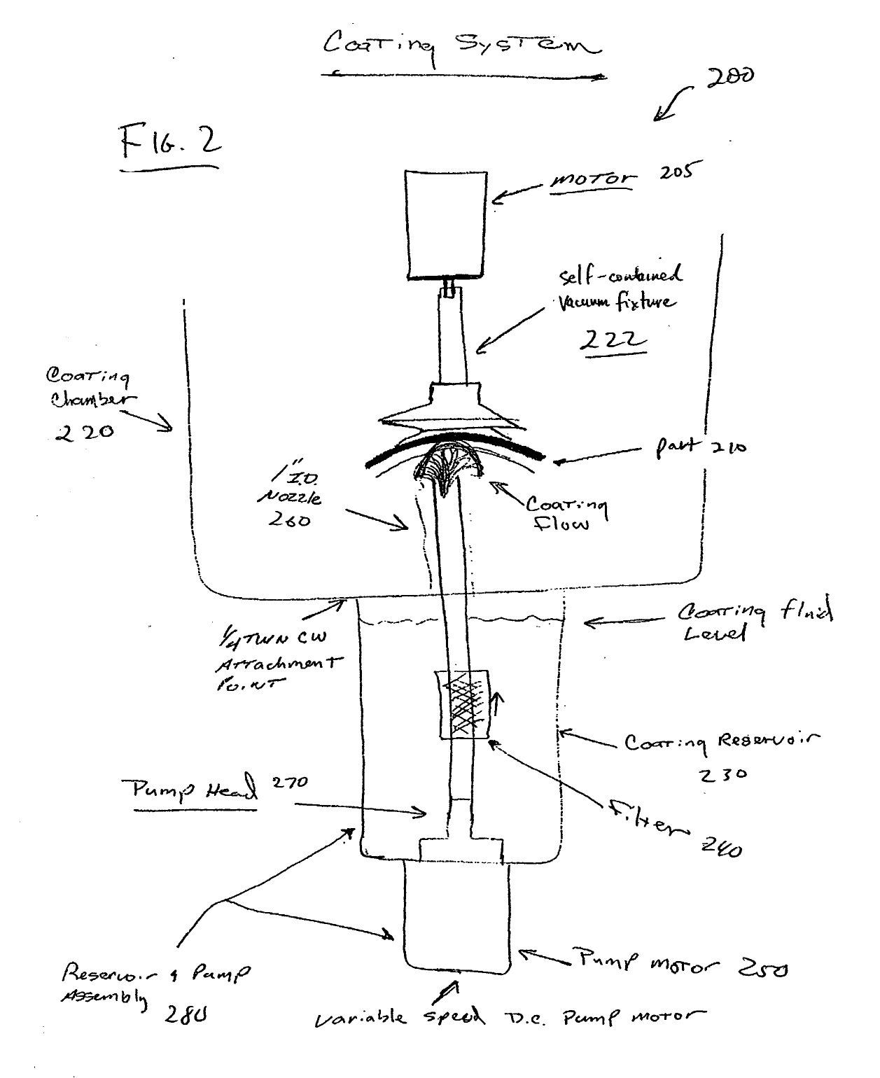

FIG. 2 is a diagram showing a coating system 200 including one embodiment of the self-contained vacuum fixture 222 with self-generated vacuum according to one embodiment of the present system. Fixture 222 holds a part 210 for coating by a chemical spray from nozzle 260. Motor 205 can turn the fixture 222 to evenly spin coat the part 210 within coating chamber 220. The chemical residing in coating reservoir 230 is pressurized by pump motor 250 and sent from pump head 270 through filter 240 to nozzle 260. The coating reservoir 230 and pump motor 250 form an assembly 280 which is attached to the coating chamber 220. In one embodiment the attachment uses a ¼ turn cw attachment point to a nylon coating chamber bottom. Such a system uses a ¼ ccw turn removal. In one embodiment the resevoir 230 is nylon material.

In one embodiment, the pump head 270 is built into the bottom of the reservoir and is magnetically coupled to the pump motor making a seal-less fit between pump head and pump motor.

The coating reservoir and pump are removable without loss of coating fluid, as there are no external fluid tubes leading to a pump or filter. This provides a quick change feature which is desireable in coating machines. This also avoids loss of fluids due to external tubes running to the pump or filter, making all fluids in the reservoir ready for coating delivery. The pump also stays primed. A shorter time is needed to apply chemicals. Chemical overspray is reduced.

In one embodiment, the lens head is lowered onto a coating fountain and the coating fans out over the lens. The lens is rotating at approximately 200 RPM to allow coating to flow over the full surface of the lens. Coating applied in this manner avoids the need for aeration of coating fluid imparted on the lens. This also leaves the lens free of pits.

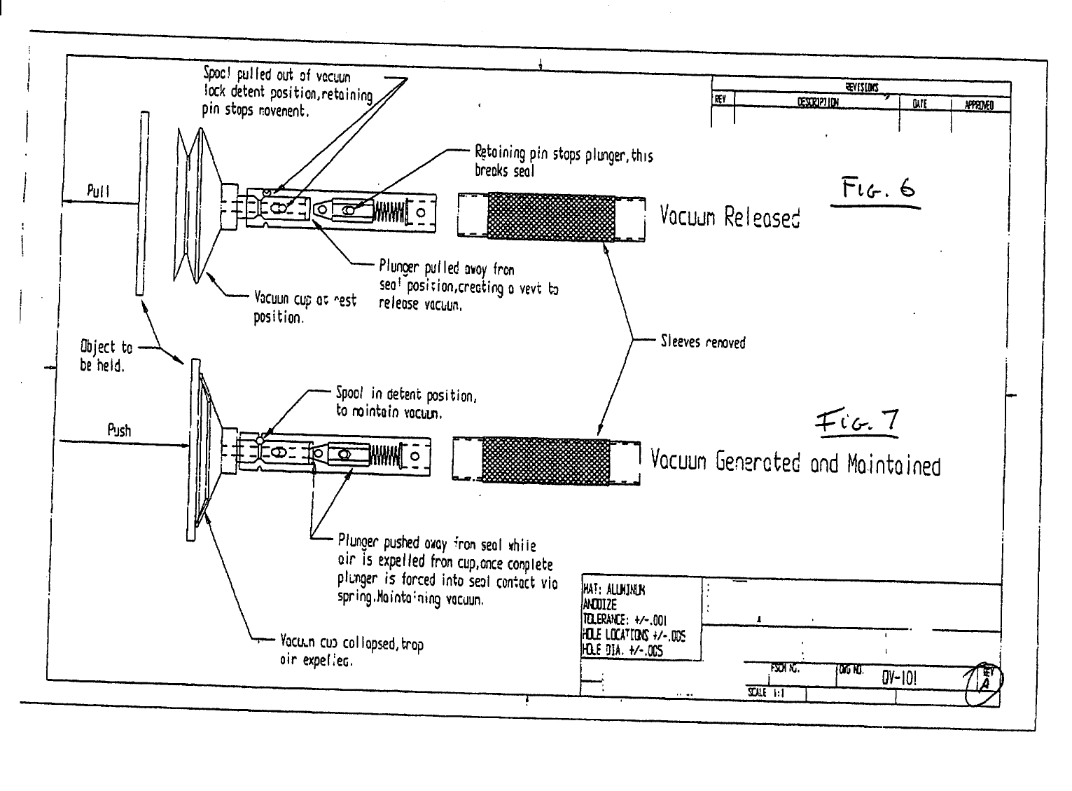

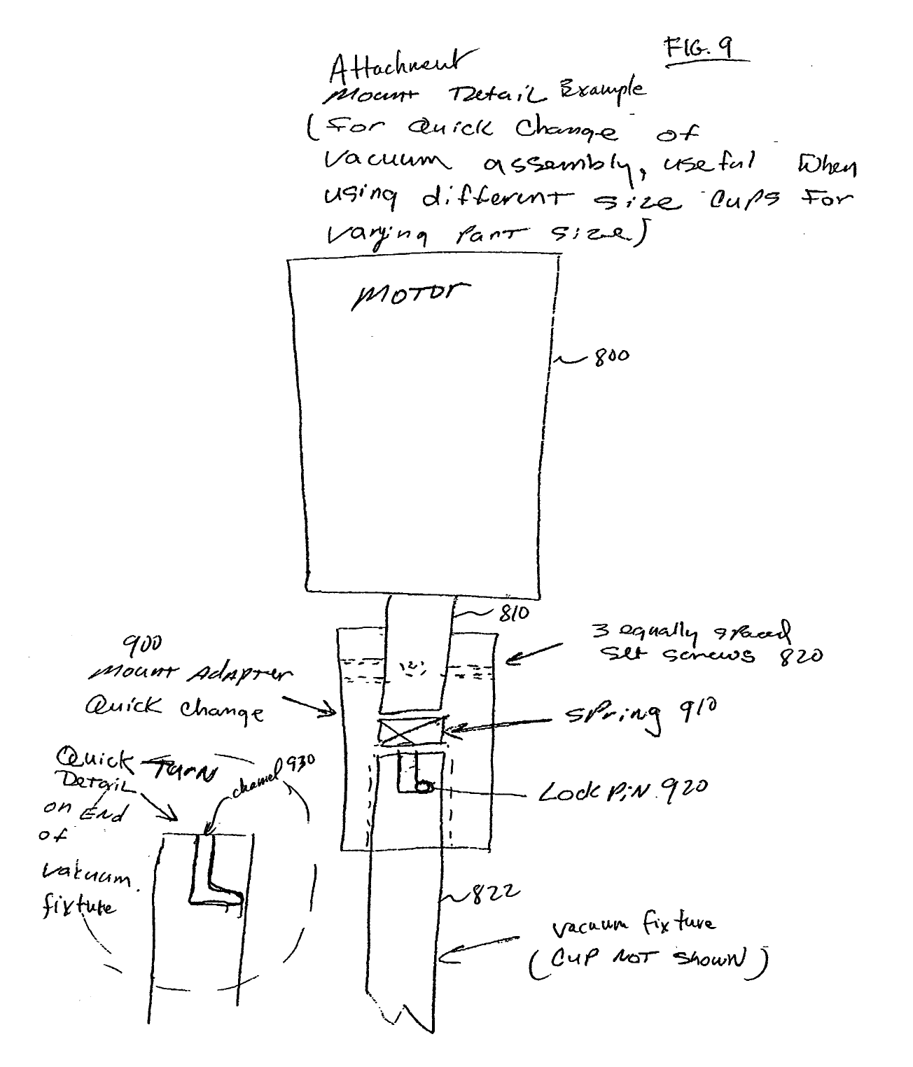

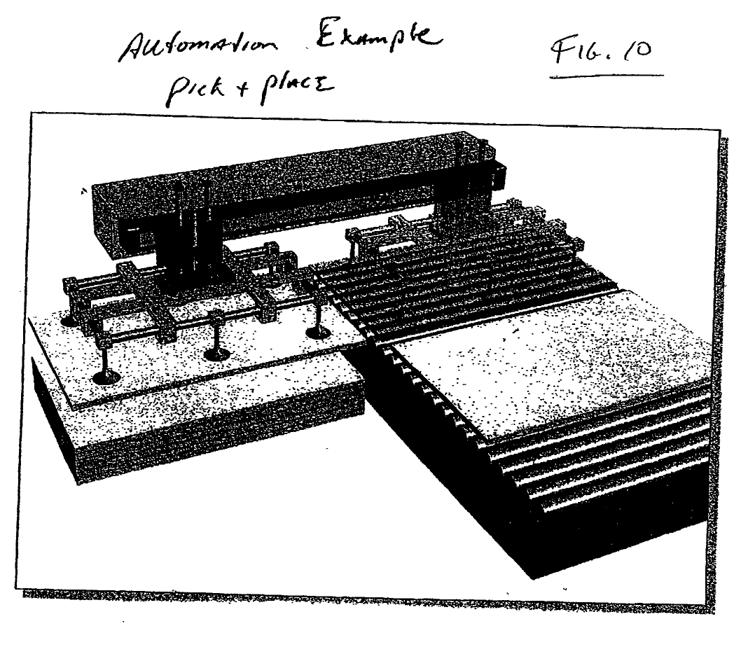

In one embodiment of the system in FIG. 2, the self-contained vacuum fixture 222 is the embodiment shown in FIG. 5 and discussed below. In one embodiment, the self-contained vacuum fixture 222 is a suction cup. In one embodiment, the attachment mount is the example of FIG. 8, discussed below. In one embodiment, the attachment mount is the example of FIG. 9, discussed below.

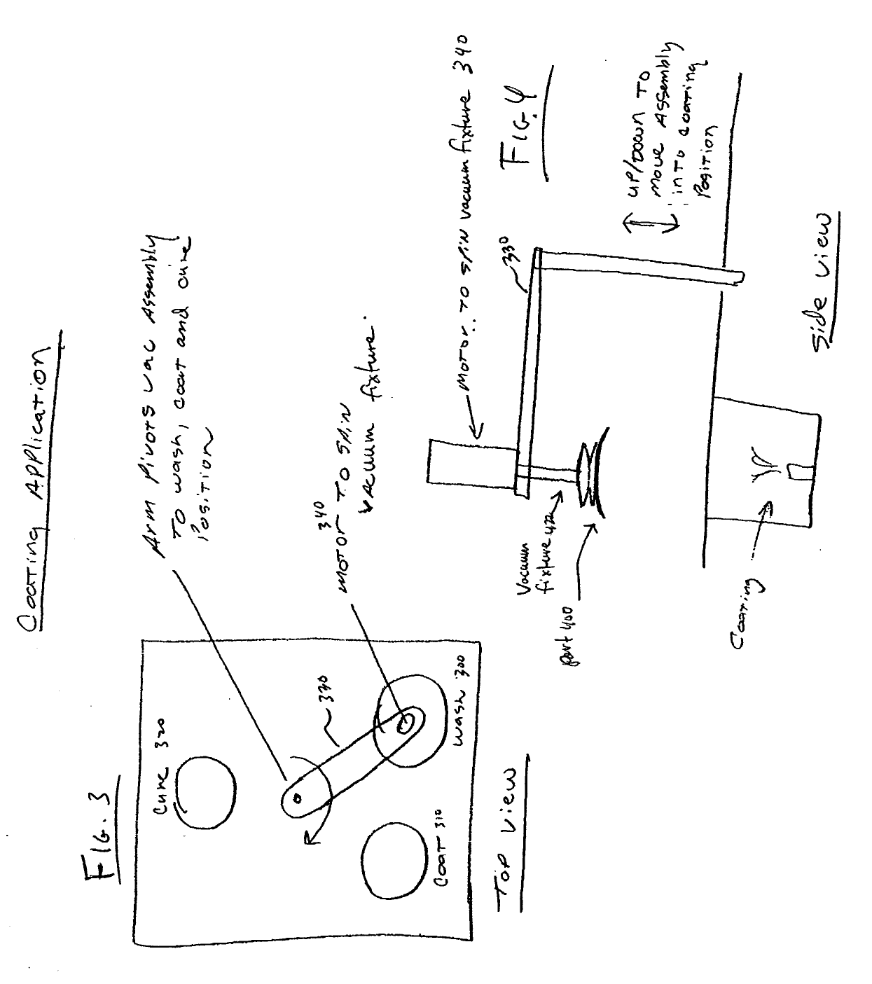

FIG. 3 is a top view diagram showing a multiple feature system including wash 300, coat 310, and cure 320 positions according to one embodiment of the present system. Arm 330 pivots to place the self-contained vacuum fixture (not shown) at the different positions. Motor 340 spins the self-contained vacuum fixture.

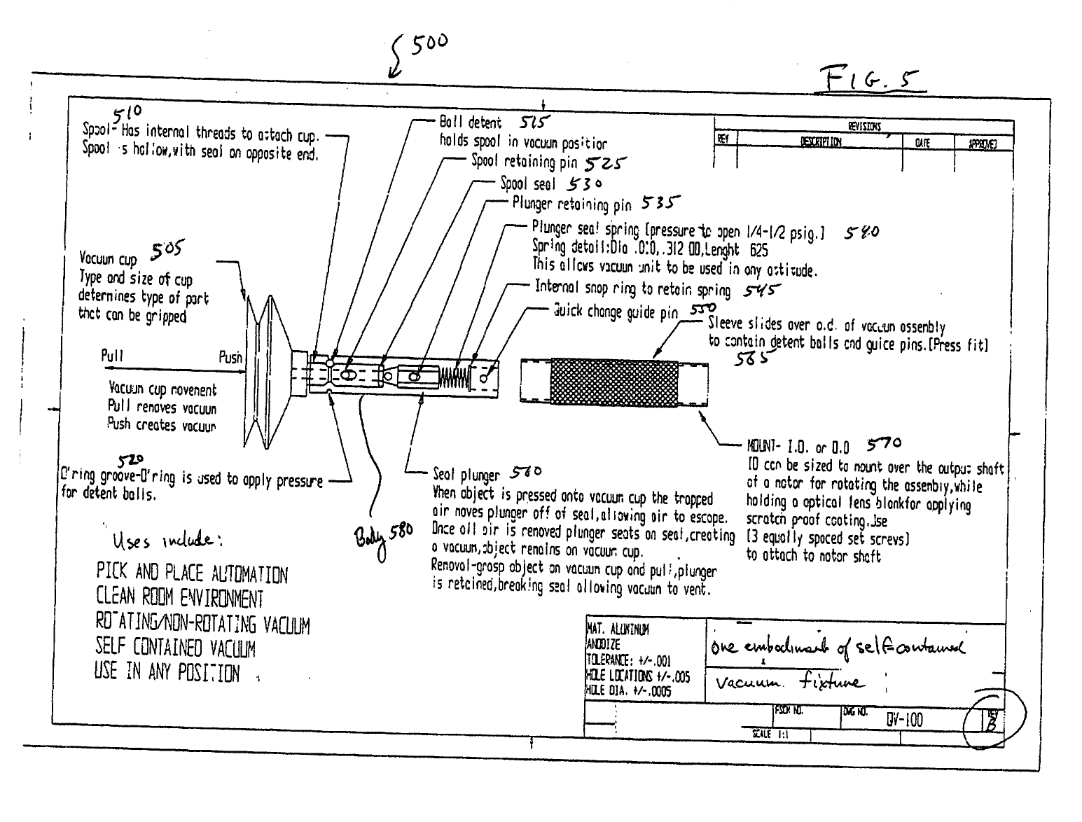

FIG. 4 is a side view of the system of FIG. 3 according to one embodiment of the present system. Arm 330 holds self-contained vacuum fixture 422 in position. Arm 330 also moves the vacuum fixture 422 up or down as required. Motor 340 spins fixture 422 and part 400.

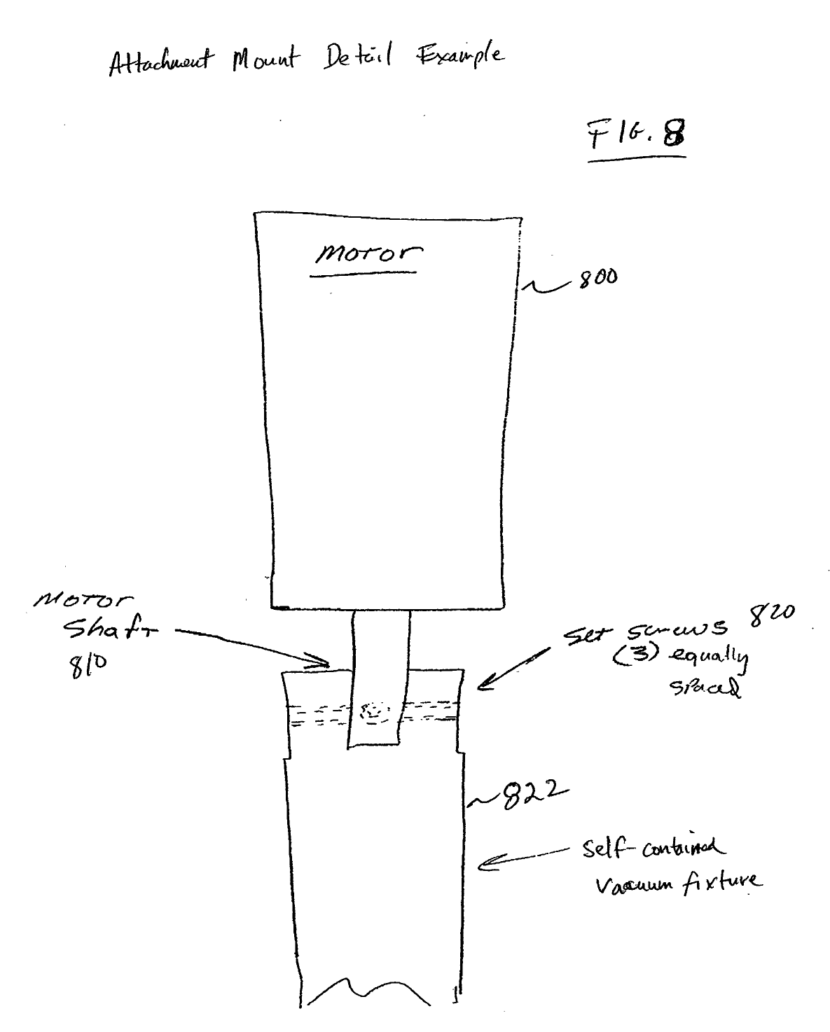

FIG. 5 is a diagram of one example of a self-contained vacuum fixture 500 according to one embodiment of the present system. In this example, fixture 500 includes a cup 505 attached to a spool 510. A ball detent 515 holds spool 510 in position as the cup/spool assembly is depressed. An o-ring 520 applies pressure to ball detent 515. When an object is pressed onto the vacuum cup 505, air is pressurized within the spool 510 and the pressurized air moves the seal plunger 560 off of seal allowing air to escape. Once air escapes the plunger 560 seats on a seal creating a vacuum on the object so that the object remains on the cup 505. The seal plunger 560 mates with spool seal 530 to maintain the vacuum and is kept in position in part with the force exerted by spring 540. FIG. 7 is a diagram of the self-contained vacuum fixture of FIG. 5 in a vacuum held state according to one embodiment of the present system.

To remove the object, it is pulled away from the cup to break its seal and dissipate the vacuum. This occurs because pulling on the object also pulls vacuum cup 505, which draws spool 510 out of body 580. As the spool 510 is drawn out of the body, the ball detent 515 will leave its groove and the seal plunger 560 is stopped by plunger retaining pin 535. After the seal plunger 560 is stopped, the vacuum is broken as the seal plunger 560 is pulled out of the spool seal 530. The object can be removed from vacuum cup 505 since the vacuum has been lost. Spool 510 cannot leave body 580 since it stops when it reaches spool retaining pin 525. The released state of the self-contained vacuum fixture of FIG. 5 is shown in FIG. 6, according to one embodiment of the present system.

This design provides an affirmative hold of the object in the held state. The design also provides a way to remove the object without excessive force on the object and the overall assembly.

In one embodiment the materials are non-ferrous. In one embodiment the materials are ferrous. In varying embodiments, differently shaped vacuum cups 505 are employed. The type of vacuum cups used are determined by the size and shape of object to be held. In one embodiment, an automatic release is used whereby the object is released with an electrical valve operation. It is understood that the vacuum fixture 500 is used in rotating embodiments. In alternate embodiments, the vacuum fixture 500 is used in non-rotating embodiments. It is understood that the vacuum fixture 500 may be used in different spatial positions and orientations.

One skilled in the art, upon reading and understanding this demonstrative embodiment, will understand that variations in the design of the self-contained vacuum fixture may occur without departing from the scope of the present invention.

FIG. 8 is a side view showing one example of attachment of the vacuum fixture according to one embodiment of the present system. The self-contained vacuum fixture 822 is attached to the motor shaft 810 of motor 800 using set screws. In the embodiment shown three set screws 820 are used; however, it is understood that other numbers of screws may be used. In alternate embodiments, other fasteners may be used without departing from the scope of the present system.

FIG. 9 is a side view showing one example of attachment of the vacuum fixture according to one embodiment of the present system. A quick change adapter 900 is used to provide a quick change between fixtures 822. In the embodiment shown, the quick change adapter 900 is attached to motor shaft 910 using set screws 820. Vacuum fixture 822 includes a channel 930 which mates with lock pin 920 when inserted into the quick change adapter 900. Spring 910 provides tension on the stem of vacuum fixture 822 to maintain lock pin 920 in fixed engagement with the channel 930. The vacuum fixture 822 is removed by an upward force and turning of the fixture.

Upon reading and understanding the specification one skilled in the art will appreciate that other quick locking mechanisms may be used.

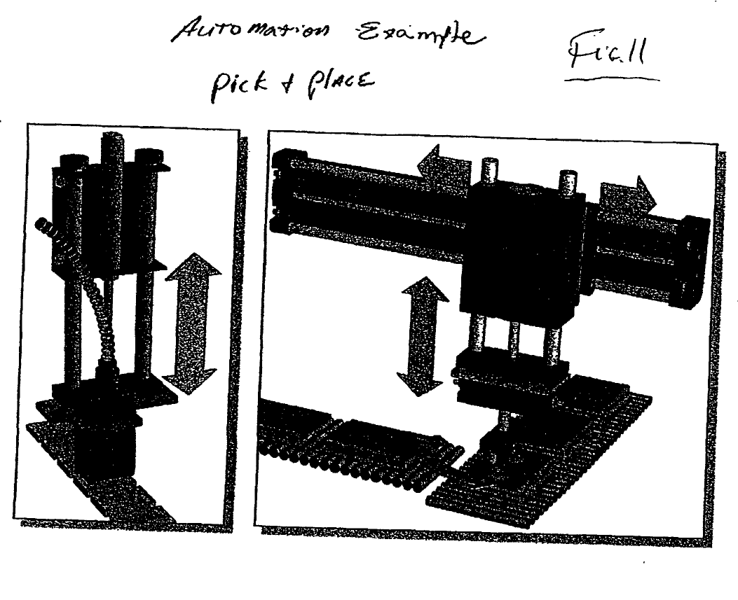

FIG. 10 and FIG. 11 show examples of a pick and place application employing the vacuum fixture according to one embodiment of the present system. In one embodiment, applications for pick and place incorporate and control electrically activated detents. In one embodiment the pick and place system controls mechanical detents. Such embodiments may be useful for applications where the heavier objects are handled.

It is also contemplated that a number of vacuum fixtures may be automatically changed using a quick change adapter and the pick and place system programmed to engage and disengage fixtures. This allows the system to use a plurality of vacuum fixtures. In one embodiment the system uses a different fixture for a differently-shaped object. In another embodiment, the system uses different fixtures having different holding forces for differently weighted objects. It is also contemplated that the system may select different fixtures for different portions of a process. Such as a chemical resistant vacuum fixture for a coating process and a heat resistant fixture for a curing process. Other variations are possible without departing from the scope and spirit of the present system.

Lens Coating Applications

In embodiments where lens coating is performed a number of chemicals and chemical processes may be employed, including coating, curing, spin coating, dip coating, cleaning. One such application is the application of scratch resistant and scratch proof coatings on optical lens blanks. The processes include the chemicals needed for each operation. It is understood that known chemical processes and chemicals may be used, including

MFR Chemical Numbers

Ultra Optics #UV-NVC COATING SOLUTION

Ultra Optics #PFD 1600 THERMAL

Ultra Optics #UV-NV COATING SOLUTION

Ultra Optics #UVX

Ultra Optics #UV 33

LTI/Colburn #SHC 3100

LTI/Colburn #HT 2000

LTI/Colburn #HT 825

LTI/Colburn #HT 150

SDC- #SILVUE 339

Those skilled in the art will understand that other processes may be performed and that other chemicals may be used with the system provided herein.

What is claimed is:

1. An apparatus for holding a part in a coating chamber, comprising:
a vacuum fixture configured to hold the part;
a motor connected to the vacuum fixture; and
an arm connected to the motor to position the vacuum fixture in the coating chamber;
wherein the vacuum fixture holds the part with a vacuum produced at the vacuum fixture and the motor spins the part for coating.

2. The apparatus of claim 1, wherein the vacuum fixture includes a vacuum cup attached to a plunger and seal for providing vacuum to the part when pressed into a hold state.

3. The apparatus of claim 1, wherein the vacuum fixture is connected to the motor via a quick change adapter.
